(19) United States
(12) Patent Application Publication
(10) Pub. No.: US 2026/0366139 A1
(43) Pub. Date: Nov. 19, 2026

(54) METHOD AND ASSEMBLY FOR SELECTIVE DEPOSITION OF METAL-CONTAINING MATERIAL

(71) Applicant: ASM IP Holding B.V., Almere (NL)

(72) Inventors: Ren Qiu, Helsinki (FI); Janne-Petteri Niemelä, Helsinki (FI); Chiyu Zhu, Helsinki (FI); Jan Willem Maes, Wilrijk (BE); Shinya Iwashita, Brussels (BE); Vincent Vandalon, Heverlee (BE); YongGyu Han, Leuven (BE); David Zanders, Leuven (BE)

(21) Appl. No.: 19/672,874

(22) Filed: May 11, 2026

Related U.S. Application Data
(60) Provisional application No. 63/805,343, filed on May 14, 2025.

(51) Int. Cl. C23C 16/04; C23C 16/02; C23C 16/44; C23C 16/455; C23C 16/52; H01J 37/32; H10P 14/43; H10P 70/00

(52) U.S. Cl. CPC C23C 16/04; C23C 16/0227; C23C 16/4408; C23C 16/45544; C23C 16/45553; C23C 16/52; H01J 37/32449; H10P 14/432; H10P 70/27; H01J 2237/332; H01J 2237/335

(57) ABSTRACT

The present disclosure relates to methods and apparatuses for depositing transition metal-containing material on a substrate by a cyclic deposition process. The method comprises providing a substrate in a reaction chamber; providing a metal-containing precursor into the reaction chamber in a vapor phase; and providing a halogen-containing reactant into the reaction chamber in a vapor phase to form a layer comprising metal on the substrate.

### CROSS-REFERENCE TO RELATED APPLICATIONS

The present application claims priority to and the benefit of U.S. Provisional Application No. 63/805,343, filed May 14, 2025, the entirety of which is incorporated by reference herein.

### FIELD OF INVENTION

The present invention relates to methods and systems for the manufacture of semiconductor devices. More particularly, the disclosure relates to methods and assemblies for depositing material comprising metal, layers comprising metal, as well as semiconductor structures and devices.

### BACKGROUND OF THE DISCLOSURE

Semiconductor device fabrication processes generally use advanced deposition methods for forming metal and metal-containing layers. Transition metals, such as molybdenum, may have many of the advantages sought in the art. For example, they may be useful as a conductor in back end of line (BEOL) or middle of line (MOL) applications, or in buried power rail or in work function layer in logic applications and in word or bit line in advanced memory applications. However, the deposition of high-quality transition metal thin films by cyclical deposition methods remains challenging due to the electropositive nature of transition metals, especially molybdenum, and its tendency to form nitride phases, for example. Thus, there is a need in the art for alternative or improved methods for depositing materials comprising one or more transition metals with low amounts of nitrogen.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of selectively depositing metal-containing material on a substrate comprising a metal surface and a dielectric surface, to a metal-containing layer on the metal surface of the substrate, to a semiconductor structure and a device containing said layer, and to selective deposition assemblies for selectively depositing metal-containing material on a substrate.

In a first aspect, a method for forming a layer comprising metal on a substrate comprising a metal surface and a dielectric surface by a selective cyclic deposition process is disclosed. The method comprises providing a substrate comprising a metal surface and a dielectric surface into a reaction chamber and executing at least one selective deposition cycle. Each deposition cycle comprises providing a metal-containing precursor in vapor phase into the reaction chamber and providing a halogen-containing reactant in vapor phase into the reaction chamber to form a layer comprising material comprising metal on a substrate.

In another aspect, a metal-containing layer produced by a selective deposition process is disclosed. The process comprises providing a substrate comprising a metal surface and a dielectric surface in a reaction chamber, pre-cleaning the metal surface with plasma, oxidizing the metal surface to form a metal oxide layer on the metal surface, pre-cleaning the metal surface with a reagent, passivating the dielectric surface, and executing at least one selective deposition cycle. The at least one selective deposition cycle comprises providing a metal-containing precursor into the reaction chamber in a vapor phase, and providing a halogen-containing reactant into the reaction chamber in a vapor phase to form a layer comprising a material comprising metal on the substrate. For fresh substrates, the plasma pre-cleaning and the controlled oxidation may be considered optional steps. Additionally, the process comprises an optional step of cooling the substrate and depositing a capping layer on the deposited layer after the at least one selective deposition cycle.

In an additional aspect, a semiconductor processing apparatus is disclosed. The semiconductor processing apparatus comprises a reaction chamber comprising a substrate support for supporting a substrate comprising a metal surface and a dielectric surface. The semiconductor processing apparatus further comprises a precursor injector system constructed and arranged to provide a metal-containing precursor and a reactant into the reaction chamber in a vapor phase, wherein the metal-containing precursor comprises an η⁶-arene ligand and a metal selected from Cr, Mo, Nb, Ta, V, or W, and wherein the reactant comprises a halogen. The semiconductor processing apparatus also comprises a metal-containing precursor source constructed and arranged to contain and evaporate the metal-containing precursor and a reactant source constructed and arranged to contain and evaporate the reactant. The semiconductor processing apparatus further comprises a controller configured to provide the metal-containing precursor and the reactant via the precursor injector system to the reaction chamber to deposit a metal-containing layer on the substrate according to a method as described herein. The semiconductor processing apparatus further comprises a pre-clean module configured to perform plasma pre-cleaning, reagent pre-cleaning, and/or passivation, and optionally a cooling station.

### BRIEF DESCRIPTION OF THE DRAWING FIGURES

The accompanying drawings, which are included to provide a further understanding of the disclosure and constitute a part of this specification, illustrate exemplary embodiments, and together with the description help to explain the principles of the disclosure. In the drawings

FIGS. 1A and 1B illustrate a block diagram of exemplary embodiments of a selective deposition process according to the current disclosure.

FIGS. 2A and 2B illustrate a block diagram of exemplary embodiments of a selective deposition process according to the current disclosure.

FIG. 3 is a schematic presentation of a deposition assembly according to the current disclosure.

FIG. 4 is another schematic presentation of a deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, any two numbers of a variable can constitute a workable range of the variable, and any ranges indicated may include or exclude the endpoints. As used herein, “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the selective deposition methods according to the current disclosure, metal-containing material is selectively deposited. In some embodiments, the material deposited according to the current disclosure consists essentially of, or consists of metal. In some embodiments, at least 60% of the material deposited is metal. In some embodiments, at least 80% or at least 90% or at least 95% or at least 99% of the material deposited is metal.

Material comprising metal may include an acceptable amount of impurities, such as nitrogen, oxygen, chlorine or other halogen, and/or hydrogen that may originate from one or more precursors or reactants used to deposit the metal-containing material.

In some embodiments, the metal-containing material may comprise less than about 30 at. %, less than about 20 at. %, less than about 10 at. %, less than about 8 at. %, less than about 7 at. %, less than about 5 at. %, or less than about 2 at. % oxygen. In some embodiments, the metal-containing material may comprise less than about 20 at. %, less than about 15 at. %, less than about 10 at. %, less than about 8 at. %, less than about 6 at. %, less than about 5 at. %, less than 4.5 at. %, or less than about 3 at. % carbon.

In some embodiments, the metal-containing material may form a layer. As used herein, the term “layer” and/or “film” can refer to any continuous or noncontinuous structure and material, such as material deposited by the methods disclosed herein. For example, a layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a noncontinuous layer serving to increase the rate of nucleation of another material. However, the seed layer may also be substantially or completely continuous.

As used herein, the term “substrate” may refer to any underlying material or materials that may be used to form, or upon which, a device, a circuit, material or a material layer may be formed. A substrate may include a conductive surface or a metal surface and a dielectric surface. The conductive surface or metal surface may comprise a metal selected from the group consisting of tungsten, ruthenium, molybdenum, cobalt, aluminum and copper. The dielectric surface may comprise a low-K material. The dielectric surface may comprise, for example, an oxide, such as silicon oxide (for example, thermal silicon oxide or native silicon oxide).

The substrate can include various topologies, such as gaps, including recesses, lines, trenches or spaces between elevated portions, such as fins, and the like formed within or on at least a portion of a layer of the substrate. The substrate may include nitrides, for example TiN, oxides, insulating materials, metallic materials, crystalline materials, epitaxial, heteroepitaxial, and/or single crystal materials. In some embodiments, the substrate comprises silicon. The substrate may comprise other materials, as described above, in addition to silicon. The other materials may form layers. In some embodiments, the substrate may further comprise a liner surface between the metal surface and the dielectric surface configured to prevent migration between the metal surface and the dielectric surface.

The current disclosure relates to deposition of materials from a vapor phase. Thus, gaseous metal-containing precursor and halogen-containing reactant are used in the methods according to the current disclosure.

In this disclosure, “gas” can include material that is a gas at normal temperature and pressure (NTP), a vaporized solid and/or a vaporized liquid, and can be constituted by a single gas or a mixture of gases, depending on the context. A metal-containing precursor may be provided to the reaction chamber in gas phase. The metal may be selected from the group consisting of Cr, Mo, Nb, Ta, V, and W. A halogen-containing reactant may be provided to the reaction chamber in gas phase. The halogen may be selected from the group consisting of iodine, chlorine, bromine, and fluorine. The term “inert gas” can refer to a gas that does not take part in a chemical reaction and/or does not become a part of a layer to an appreciable extent. Exemplary inert gases include He, Ar, and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In the current disclosure, the deposition process may comprise a cyclic deposition process, such as an atomic layer deposition (ALD) process. The term “cyclic deposition process” can refer to the sequential introduction of precursor(s) and/or reactant(s) into a reaction chamber to deposit material, such as a metal or semimetal-containing material, on a substrate. Cyclic deposition includes processing techniques such as atomic layer deposition (ALD). The process may comprise a purge step between providing precursors or between providing a precursor and a reactant in the reaction chamber.

The process may comprise one or more cyclic phases. For example, pulsing of a metal-containing precursor and halogen-containing reactant may be repeated. In some embodiments, the process comprises one or more acyclic phases. In some embodiments, the deposition process comprises the continuous flow of at least one precursor. In some embodiments, a reactant may be continuously provided in the reaction chamber. In such an embodiment, the process comprises a continuous flow of a precursor or a reactant. In some embodiments, one or more of the precursors and/or reactants are provided in the reaction chamber continuously. In some embodiments, auxiliary reactant may be provided in the reaction chamber continuously.

The term “atomic layer deposition” (ALD) can refer to a vapor deposition process in which deposition cycles, such as a plurality of consecutive deposition cycles, are conducted in a reaction chamber. Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a transition metal precursor into the reaction chamber. In some embodiments, the cyclic deposition process comprises purging the reaction chamber after providing a second precursor into the reaction chamber. In some embodiments, the cyclic deposition process comprises purging the reaction chamber after providing any precursor or reactant into the reaction chamber.

In some embodiments, the reaction chamber is purged after providing a metal-containing precursor and/or a second precursor therein. As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example, in the case of temporal purges, a purge step can be used e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 1 s, 2 s or 3 s. However, other purge times can be utilized if necessary, such as where highly conformal step coverage over extremely high aspect ratio structures or other structures with complex surface morphology is needed, or in specific reactor types, such as a batch reactor, may be used.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of metal-containing material in the absence of other external energy sources, such as plasma, radicals, or other forms of radiation. In some embodiments, the cyclic deposition process according to the current disclosure is a fully thermal process, i.e., it does not comprise plasma steps. However, in some embodiments, the method comprises at least one plasma-enhanced step. In some embodiments, the method according to the current disclosure is a plasma-enhanced deposition method, for example, PEALD.

The methods according to the current disclosure comprise providing a substrate in a reaction chamber, providing a metal-containing precursor into the reaction chamber in a vapor phase, and providing a halogen-containing reactant into the reaction chamber in a vapor phase to form metal-containing material on the metal surface of the substrate.

The method of depositing transition metal-containing material according to the current disclosure comprises providing a substrate in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously. A reaction chamber according to the current disclosure may further be a deposition station in a multi-station chamber.

In the method according to the current disclosure, the metal-containing precursor may be in vapor phase when it is in a reaction chamber. The metal-containing precursor may be partially gaseous or liquid, or even solid at some points in time prior to being provided in the reaction chamber. In other words, the precursor may be solid, liquid or gaseous, for example, in a precursor vessel or other receptacle before delivery in a reaction chamber. Various means of bringing the precursor in to gas phase can be applied when delivery into the reaction chamber is performed. Such means may include, for example, heaters, vaporizers, gas flow or applying lowered pressure, or any combination thereof. Thus, the method according to the current disclosure may comprise heating the precursor prior to providing it to the reaction chamber.

In some embodiments, the deposition of a metal-containing material according to the current disclosure is performed at a temperature below about 400 °C, or below about 350 °C, or below about 320 °C. In some embodiments, the deposition is performed at a temperature from about 240 °C to about 310 °C, for example from about 200 °C to about 300 °C, such as at a temperature of about 250 °C, about 275 °C or at about 300 °C.

In some embodiments, a precursor is heated to at least 30 °C, to at least 50 °C, or to at least 70 °C, or to at least 90 °C or to at least 100 °C or to at least 110 °C before providing it to the reaction chamber. In some embodiments, a precursor is heated to at least 70 °C, or to at least 75 °C. The heating may take place in a precursor vessel. In some embodiments, the precursor is heated to at most 110 °C, or to at most 100 °C, or to at most 90 °C, or to at most 80 °C, before providing it to the reaction chamber. The injector system of a vapor deposition assembly may be heated to improve the vapor-phase delivery of the precursor to the reaction chamber.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may mean element or a compound that is not incorporated into the resulting compound or element to a significant extent. However, a reactant may also contribute to the resulting compound or element in certain embodiments, or it may modify the properties of the deposited material.

As used herein, “a metal-containing precursor” includes a gas or a material that can become gaseous and that can be represented by a chemical formula that includes the target metal. By “a target metal” it is meant the metal in the precursor that is intended to be selectively deposited. Examples of target metals include chromium (Cr), molybdenum (Mo), niobium (Nb), tantalum (Ta), vanadium (V), and tungsten (W).

In the present disclosure, the metal of the metal-containing precursor is Cr, Mo, Nb, Ta, V, or W. In an embodiment, the metal is Cr. In an embodiment, the metal is Mo. In an embodiment, the metal is Nb. In an embodiment, the metal is Ta. In an embodiment, the metal is V. In an embodiment, the metal is W. In some embodiments, the metal is selected from the group consisting of Cr, Mo, Nb, and W. In some embodiments, the metal is selected from the group consisting of Cr, Mo, and W. In some embodiments, the metal is selected from the group consisting of Mo, Nb and W. In some embodiments, the metal is selected from the group consisting of Mo and W. Molybdenum (Mo) may be a particularly suitable functional group for use in the present disclosure because Mo has a very low resistivity and a high melting point, and can be readily integrated in semiconductor devices without the need for any barrier or liner materials. In some embodiments, more than one type of metal-containing precursor is used, e.g., a first metal-containing precursor comprising a first metal selected from Cr, Mo, Nb, Ta, V, or W and a second metal-containing comprising a second metal different from the first metal selected from Cr, Mo, Nb, Ta, V, or W.

As used herein, the term “arene” refers to an aromatic hydrocarbon characterized by one or more ring structures, e.g., a benzene ring, that possess a conjugated system of π-electrons.

As used herein, η^{x} where x=an integer refers to the number of carbons that interact with (e.g., donate electrons to) a metal atom in the precursor, e.g., η²-alkene (2 such carbon atoms), η²-alkyne (2 such carbon atoms), η³-allyl (3 such carbon atoms), and η4-1,3-butadiene (4 such carbon atoms).

As used herein, the term η⁶-arene thus refers to an aromatic ring that coordinates to a metal center through six of its carbon atoms. In this instance, the arene acts as a ligand by donating six π electrons to the metal, forming a stable complex. A well-known example is (η⁶-benzene)chromium tricarbonyl, where benzene coordinates to chromium in an η⁶ manner, meaning all six carbons of the benzene ring interact with the metal center.

As used herein, the term “alkyl” refers to a fully saturated aliphatic hydrocarbon group. The alkyl group may be branched, straight chain, or cyclic (i.e., a cycloalkyl). Examples of branched alkyl groups include, but are not limited to, iso-propyl, sec-butyl, t-butyl, and the like. Examples of straight chain alkyl groups include, but are not limited to, methyl, ethyl, n-propyl, n-butyl, n-pentyl, n-hexyl, n-heptyl, and the like. As used herein, the term “cycloalkyl” refers to a completely saturated (no double or triple bonds) mono- or multi-cyclic hydrocarbon ring system. Exemplary cycloalkyl groups include, but are not limited to, cyclopropyl, cyclobutyl, cyclopentyl, cyclohexyl, cycloheptyl and cyclooctyl, and the like. The alkyl group may be substituted or unsubstituted.

As used herein, the terms “alkenyl” refers to a group of two or more carbons containing one or more carbon double bonds. The alkenyl group may be branched, straight chain, or cyclic (i.e., cycloalkenyl). As used herein, the term “cycloalkenyl” refers to a mono- or multi-cyclic hydrocarbon ring system that contains one or more double bonds in at least one ring. Exemplary alkenyl groups include 1-propenyl, 2-propenyl, 2-methyl-l-propenyl, 1-butenyl, 2-butenyl, and the like. The alkenyl group may be unsubstituted or substituted.

As used herein, the term “alkynyl” refers to a group of two or more carbons containing one or more carbon triple bonds. The alkynyl group may be branched, straight chain, or cyclic (i.e., cycloalkynyl). As used herein, the term “cycloalkynyl” refers to a mono- or multi-cyclic hydrocarbon ring system that contains one or more triple bonds in at least one ring. Exemplary alkenyl group include 1-propynyl, 1-butynyl, 2-butynyl, and the like. The alkynyl group may be unsubstituted or substituted.

As used herein, the term “aryl” refers to a carbocyclic (all carbon), monocyclic, or multicyclic aromatic ring system (including fused ring systems where two carbocyclic rings share a chemical bond) that has a fully delocalized pi-electron system throughout all the rings. The number of carbon atoms in an aryl group can vary, such as from C6 to C10. Exemplary aryl groups include, but are not limited to, benzene, naphthalene and azulene. An aryl group may be substituted or unsubstituted.

In some embodiments, the metal-containing precursor comprises an η⁶-arene ligand and a metal selected from Cr, Mo, Nb, Ta, V, or W. The η⁶-arene ligand may comprise one alkyl substituent, or two or more alkyl substituents. The alkyl substituent comprises from 1 to 10 carbon atoms that can be in a straight chain, branched chain, or cyclic ring configuration, or a combination thereof. In some embodiments, the alkyl substituent is selected from the group consisting of methyl, ethyl, 1-propyl, isopropyl, 1-butyl, 2-butyl, isobutyl, tert-butyl, 1-pentyl, 2-pentyl, 3-pentyl, isopentyl, tert-pentyl, neo-pentyl, cyclopentyl, 1-hexyl, and cyclohexyl. In some embodiments, the η⁶-arene ligand is selected from the group consisting of η⁶-benzene, η⁶-toluene, η⁶-ethylbenzene, η⁶-1,2-dimethylbenzene, η⁶-1,3-dimethylbenzene, η⁶-1,4-dimethylbenzene, and η⁶-1,3,5-trimethylbenzene. In some embodiments, the metal-containing precursor comprises two η⁶-arene ligands. In some embodiments, the metal-containing precursor comprises one η⁶-arene ligand and at least one second ligand, wherein the at least one second ligand is a different ligand from the η⁶-arene ligand. The at least one second ligand may be selected from the group consisting of carbonyl, nitrosyl, trialkyl amine, trialkyl phosphine, trialkyl phosphite, N-heterocyclic carbene, η²-alkene, η²-alkyne, η³-allyl, and η⁴-1,3-butadiene.

In some embodiments, the metal-containing precursor comprises bis(ethylbenzene)molybdenum, and the deposited layer comprises metallic molybdenum or molybdenum carbide.

In some embodiments, the halogen-containing reactant comprises a compound according to Formula (I):

SiₓH_{(2x+2-y)}A_{y} (I)
wherein x is an integer from 1 to 10,
wherein y is an integer from 1 to 10, and
wherein A comprises a halogen.

In some embodiments, x is an integer from 1 to 5, or from 1 to 3. In some embodiments, y is an integer from 1 to 5, or 1 to 4, or 1 to 3.

In some embodiments, halogen-containing reactant comprises an alkyl group. In some embodiments, the halogen-containing reactant contains no carbon. In some embodiments, the halogen-containing reactant is selected from the group consisting of iodosilane, iododisilane, 1,2-diiododisilane, tetraiodosilane, chlorosilane, chlorodisilane, 1,2-dichlorodisilane, tetrachlorosilane, bromosilane, bromodisilane, 1,2-dibromodisilane, tetrabromosilane, ethyl iodosilane, diiododimethylsilane, iodotrimethylsilane, ethyl chlorosilane, dichlorodimethylsilane, chlorotrimethylsilane, ethyl bromosilane, dibromodimethylsilane, bromotrimethylsilane, 1,2-diiodoethane, iodobutane, 1,2-dichloroethane, chlorobutane, 1,2-dibromoethane, and bromobutane.

In some embodiments, the method of selectively depositing a material comprising metal on a substrate comprises:
providing a substrate comprising a metal surface and a dielectric surface in a reaction chamber;
executing at least one selective deposition cycle, wherein the at least one selective deposition cycle comprises:
   providing a metal-containing precursor in vapor phase into the reaction chamber,
   wherein the metal-containing precursor comprises an η⁶-arene ligand and a metal selected from Cr, Mo, Nb, Ta, V, or W; and
   providing a reactant in vapor phase into the reaction chamber, wherein the reactant comprises a halogen,
to form a layer comprising the material comprising metal on the metal surface of the substrate.

In some embodiments, the method of selectively depositing a material comprising metal on a substrate may further comprise steps of pre-cleaning, oxidizing, and passivating, before executing at least one selective deposition cycle. More specifically, the method may further comprise pre-cleaning the metal surface with plasma. In some embodiments, the plasma may be direct plasma. The direct plasma may comprise hydrogen ions generated in the reaction chamber. In some embodiments, the plasma may be remote plasma. The plasma pre-cleaning removes any metal oxide impurities that may exist on the metal surface or the dielectric surface. The plasma pre-cleaning may also remove benzotriazole (BTA) that may exist on the substrate. The plasma pre-cleaning may be performed at a temperature below about 300 °C, or below about 270 °C, or at a temperature from about 150 °C to about 260 °C, for example from about 200 °C to about 250 °C, such as at a temperature of about 240 °C or about 250 °C.

After the plasma pre-cleaning, the method may further comprise a controlled oxidation of the metal surface of the substrate, to form a metal oxide layer on the metal surface.

After the oxidizing, the method may further comprise pre-cleaning the substrate with a reagent, which removes any metal oxide impurities and/or the metal oxide intentionally formed by the oxidizing step. The reagent may be selected from the group consisting of glyoxal, malondialdehyde, succinaldehyde, phtalaldehyde (aromatic backbone), glutaraldehyde, isophtalaldehyde (aromatic backbone), adipaldehyde, 2,3-butandione, 2,3-pentandione, 2,3-hexandione, benzil, dimedone, 1,2-indandione, acetylacetone, trifluoroacetylacetone, hexafluoroacetylacetone, 1,3-cyclohexanedione, 2,2,6,6-tetramethyl-3,5-heptanedione, 2,5-hexandione, and methylglyoxal. The reagent pre-cleaning may be performed at a temperature below about 300 °C, or below about 270 °C, or at a temperature from about 150 °C to about 260 °C, for example from about 200 °C to about 250 °C, such as at a temperature of about 240 °C or about 250 °C.

After the reagent pre-cleaning, the method may further comprise passivating the dielectric surface before the at least one selective deposition cycle. The passivation is performed by applying an inhibitor reactant on the dielectric surface, whereby selectivity of the at least one selective deposition to the metal surface is enhanced. In some embodiments, the inhibitor reactant comprises silicon. In some embodiments, the inhibitor reactant comprises a Si—N bond or a Si-halogen bond. In some embodiments, the inhibitor reactant has a formula SiR₃NR′₂, wherein each R is independently selected from C1 to C5 alkyls and alkoxides, and each R′ is independently selected from C1 to C7 alkyls. In some embodiments, the inhibitor reactant is selected from a group consisting of Si(Me)₃N(Me)₂, Si(Me)₃N(Et)₂, Si(Me)₃N(Me)(Et), Si(Et)₃N(Me)₂, Si(Et)₃N(Et)₂, Si(Et)₃N(Me)(Et), Si(Pr)₃N(Me)₂, Si(Pr)₃N(Et)₂, Si(Pr)₃N(Me)(Et), Si(Et)₂(Me)N(Me)₂, Si(Et)₂(Me)N(Et)₂, Si(Et)₂(Me)N(Me)(Et), Si(Et)(Me)₂N(Me)₂, Si(Et)(Me)₂N(Et)₂, Si(Et)(Me)₂N(Me)(Et), Si(OMe)₃N(Me)₂, Si(OMe)₃N(Et)₂, Si(OMe)₃N(Me)(Et), Si(OEt)₃N(Me)₂, Si(OEt)₃N(Et)₂, Si(OEt)₃N(Me)(Et), Si(OPr)₃N(Me)₂, Si(OPr)₃N(Et)₂, Si(OPr)₃N(Me)(Et), Si(Me) (OMe)₂N(Me)₂, Si(Me)(OMe)₂N(Et)₂, Si(Me)(OMe)₂N(Me)(Et), Si(Me)(OEt)₂N(Me)₂, Si(Me)(OEt)₂N(Et)₂, Si(Me)(OEt)₂N(Me)(Et), Si(Me)(OPr)₂N(Me)₂, Si(Me)(OPr)₂N(Et)₂, Si(Me)(OPr)₂N(Me)(Et), Si(Me)₂(OMe)N(Me)₂, Si(Me)₂(OMe)N(Et)₂, Si(Me)₂(OMe)N(Me)(Et), Si(Me)₂(OEt)N(Me)₂, Si(Me)₂(OEt)N(Et)₂, Si(Me)₂(OEt)N(Me) (Et), Si(Me)₂(OPr)N(Me)₂, Si(Me)₂(OPr)N(Et)₂, Si(Me)₂(OPr)N(Me)(Et), Si(Et) (OMe)₂N(Me)₂, Si(Et)(OMe)₂N(Et)₂, Si(Et)(OMe)₂N(Me)(Et), Si(Et)(OEt)₂N(Me)₂, Si(Et) (OEt)₂N(Et)₂, Si(Et)(OEt)₂N(Me)(Et), Si(Et)(OPr)₂N(Me)₂, Si(Et)(OPr)₂N(Et)₂, Si(Et) (OPr)₂N(Me)(Et), Si(Et)₂(OMe)N(Me)₂, Si(Et)₂(OMe)N(Et)₂, Si(Et)₂(OMe)N(Me)(Et), Si(Et)₂(OEt)N(Me)₂, Si(Et)₂(OEt)N(Et)₂, Si(Et)₂(OEt)N(Me)(Et), Si(Et)₂(OPr)N(Me)₂, Si(Et)₂(OPr)N(Et)₂, Si(Et)₂(OPr)N(Me)(Et), Si(OEt)₂(OMe)N(Me)₂, Si(OEt)₂(OMe)N(Et)₂, Si(OEt)₂(OMe)N(Me)(Et), Si(OEt)(OMe)₂N(Me)₂, Si(OEt) (OMe)₂N(Et)₂, Si(OEt)(OMe)₂N(Me)(Et), SiMe₂(NMe₂)₂, SiMe₂(NEt₂)₂, SiMe₂(N(Me) (Et))₂, SiMe₂(NPr₂)₂, SiMe₂(NⁱPr₂)₂, SiEt₂(NMe₂)₂, SiEt₂(NEt₂)₂, SiEt₂(N(Me)(Et))₂, SiEt₂(NPr₂)₂, SiEt₂(NⁱPr₂)₂, SiPr₂(NMe₂)₂, SiPr₂(NEt₂)₂, SiPr₂(N(Me)(Et))₂, SiPr₂(NPr₂)₂, SiPr₂(NⁱPr₂)₂, Si(Me)₃Pyr, Si(Et)₃Pyr, Si(ⁱPr)₃Pyr, Si(Pr)₃Pyr, Si(ⁿBu)₃Pyr, Si(^{s}Bu)₃Pyr, Si(ⁱBu)₃Pyr, Si(^{t}Bu)₃Pyr, Si(Me)₃Im, Si(Et)₃Im, Si(ᵢPr)₃Im, Si(Pr)₃Im, Si(ₙBu)₃Im, Si(^{s}Bu)₃Im, Si(ⁱBu)₃Im, Si(^{t}Bu)₃Im, SiClMe₃, SiCl₂Me₂, SiCl₃Me, SiClEt₃, SiCl₂Et₂, SiCl₃Et, SiClPr₃, SiCl₂Pr₂, SiCl₃Pr, SiClⁱPr₃, SiCl₂ⁱPr₂, SiCl₃ⁱPr, SiCl^{t}Bu₃, SiCl₂^{t}Bu₂, SiCl₃^{t}Bu, SiBrMe₃, SiBr₂Me₂, SiBr₃Me, SiBrEt₃, SiBr₂Et₂, SiBr₃Et, SiBrPr₃, SiBr₂Pr₂, SiBr₃Pr, SiBrⁱPr₃, SiBr₂ⁱPr₂, SiBr₃ⁱPr, SiBr^{t}Bu₃, SiBr₂^{t}Bu₂, SiBr₃^{t}Bu, SiIMe₃, SiI₂Me₂, SiI₃Me, SiIEt₃, SiI₂Et₂, SiI₃Et, SiIPr₃, SiI₂Pr₂, SiI₃Pr, SiIⁱPr₃, SiI₂ⁱPr₂, SiI₃ⁱPr, SiI^{t}Bu₃, SiI₂^{t}Bu₂, SiI₃^{t}Bu, wherein Me stands for methyl, Et for ethyl, OMe for methoxy, OEt for ethoxy, Pr for n-propyl, ⁱPr for isopropyl, ⁿBu for n-butyl, ^{s}Bu for sec-butyl, ⁱBu for isobutyl, ^{t}Bu for tert-butyl, Pyr for pyrrole, Im for imidazole, and wherein pyrrole or imidazole, respectively, is attached to the silicon atom through nitrogen and OMe or OEt, respectively, through the alkoxy oxygen. In some embodiments, the inhibitor reactant is selected from a group consisting of N-(trimethylsilyl)dimethylamine, 1-(triisopropylsilyl)pyrrole, 1-(trimethylsilyl)imidazole, 1,1,1-trimethoxy-N,N-dimethylsilanamine, bis(dimethylamino)dimethylsilane, bis(dimethylamino)diethylsilane and chlorotrimethylsilane. In some embodiments, more than one inhibitor reactant may be applied. The inhibitor reactants may be applied simultaneously (co-dosing) or sequentially.

The passivation may be performed at a temperature below about 300 °C, or below about 270 °C, or at a temperature from about 150 °C to about 260 °C, for example, from about 200 °C to about 250 °C, such as at a temperature of about 240 °C or about 250 °C. After the passivation, at least one selective deposition cycle is performed.

For aged substrates, the method may comprise all of the above steps. For fresh substrates, the plasma pre-cleaning and the controlled oxidation may be considered optional steps. In some embodiments, the plasma pre-cleaning and the controlled oxidation are performed. In some embodiments, the plasma pre-cleaning and the controlled oxidation may not be performed, if a fresh substrate is used.

In some embodiments, the method may further comprise cooling the substrate and depositing a capping layer on the deposited layer after the at least one selective deposition cycle. The cooling may be performed in vacuum.

In some embodiments, the order of the above steps in the method for selectively depositing is: providing substrate comprising a metal surface and a dielectric surface in a reaction chamber, pre-clean metal surface with plasma, oxidize metal surface of substrate, pre-clean metal surface with a reagent, passivate dielectric surface by applying an inhibitor reactant on the dielectric surface, and execute at least one selective deposition cycle. One selective deposition cycle is executed by providing metal-containing precursor in the reaction chamber and providing halogen-containing reactant in the reaction chamber. Optionally, the reaction chamber may be purged between providing precursor and providing reactant. Optionally, reactant can be provided before providing precursor.

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

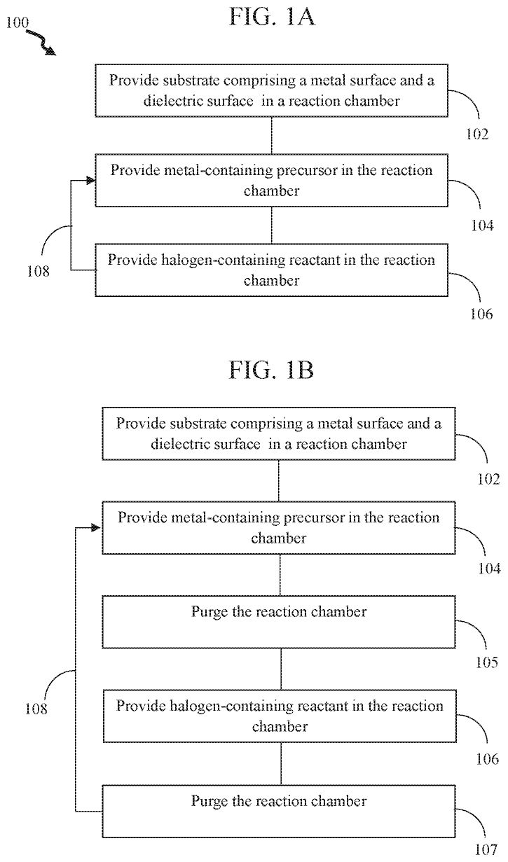

FIGS. 1A and 1B illustrate a block diagram of an exemplary embodiment of a method 100 of selectively depositing metal-containing material on a substrate. In the first phase 102, a substrate comprising a metal surface and a dielectric surface is provided into a reaction chamber. A substrate according to the current disclosure may comprise, for example, an oxide surface, such as a silicon oxide surface (for example, thermal silicon oxide or native silicon oxide), and a metal surface, such as copper, cobalt or tungsten. The metal-containing material according to the current disclosure may be deposited on said metal surface.

The reaction chamber can form part of an atomic layer deposition (ALD) assembly. The assembly may be a single wafer reactor. Alternatively, the reactor may be a batch reactor. The assembly may comprise one or more multi-station deposition chambers. Various phases of method 100 can be performed within a single reaction chamber or they can be performed in multiple reaction chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The metal-containing material according to the current disclosure may be deposited in a cross-flow reaction chamber. The metal-containing material according to the current disclosure may be deposited in a showerhead reaction chamber.

Metal-containing precursor is provided in the reaction chamber containing the substrate in phase 104. Without limiting the current disclosure to any specific theory, metal-containing precursor may chemisorb on the substrate during providing metal-containing precursor into the reaction chamber. The duration of providing metal-containing precursor into the reaction chamber (metal-containing precursor pulse time) may be, for example, 0.5 seconds, 1 second, 1.5 seconds, 2 seconds, 3 seconds, 4 seconds or 5 seconds.

In the second deposition phase 106 of the method 100, a halogen-containing reactant is provided in the reaction chamber. The duration of providing halogen-containing reactant into the reaction chamber (halogen-containing reactant pulse time) may be, for example, 0.5 seconds, 1 second, 1.5 seconds, 2 seconds, 3 seconds, 4 seconds or 5 seconds.

Phases of providing a metal-containing precursor 104 and providing a halogen-containing reactant 106 may be performed in any order. The phases of providing a metal-containing precursor 104 and providing a halogen-containing reactant 106 may constitute a deposition cycle, resulting in the deposition of metal-containing material. In some embodiments, the two phases 104 and 106, namely providing the precursor and the reactant in the reaction chamber, may be repeated (loop 108). Such embodiments contain several deposition cycles. The thickness of the deposited metal-containing material may be regulated by adjusting the number of deposition cycles. The deposition cycle (loop 108) may be repeated until a desired metal-containing material thickness is achieved. For example, about 50, 100, 200, 300, 400, 500, 700, 800, 1,000, 1,200, 1,500, 2,000, 2,400 or 3,000 deposition cycles may be performed. The cyclical deposition may result in the formation of a metal-containing layer. The layer may be substantially continuous or continuous.

In some embodiments, the cyclic deposition process comprises providing the metal-containing precursor and the reactant alternately and sequentially in the reaction chamber. In some embodiments, the reaction chamber is purged between providing precursor and providing reactant, 105, 107, as depicted in FIG. 1B. In such embodiments, a deposition cycle may be considered to contain phases 104, 105, 106, and 107. As above, a deposition cycle may be repeated 108 a number of times to achieve desired metal-containing material thickness.

Metal-containing precursor and halogen-containing reactant may be provided in the reaction chamber in separate steps (104 and 106). FIG. 1B illustrates an embodiment according to the current disclosure, where steps 104 and 106 are separated by purge steps 105 and 107. In such embodiments, a deposition cycle comprises one or more purge steps 105, 107. During purge steps, precursor and/or reactant can be temporally separated from each other by inert gases, such as argon (Ar), nitrogen (N²) or helium (He) and/or a vacuum pressure. The separation of precursor and reactant may alternatively be spatial.

Purging the reaction chamber 105, 107 may prevent or mitigate gas-phase reactions between a precursor and a reactant, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a metal-containing precursor and a halogen-containing reactant. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 100, metal-containing material is deposited onto the substrate. The deposition process may be a cyclical deposition process, and may include cyclical ALD.

In some embodiments, the metal-containing precursor is brought into contact with a substrate surface 104, excess precursor is partially or substantially completely removed by an inert gas or vacuum 105, and reactant is brought into contact with the substrate surface comprising the precursor. The metal-containing precursor may be brought in to contact with the substrate surface in one or more pulses. In other words, pulsing of the metal-containing precursor may be repeated. The metal-containing precursor on the substrate surface may react with the halogen-containing reactant to form metal-containing material on the metal surface of the substrate. Also pulsing of the reactant 106 may be repeated. In some embodiments, reactant may be provided in the reaction chamber first 106. Thereafter, the reaction chamber may be purged 107 and precursor may be provided in the reaction chamber in one or more pulses 104.

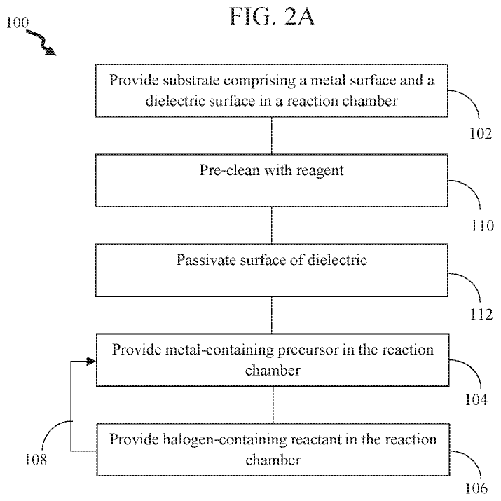

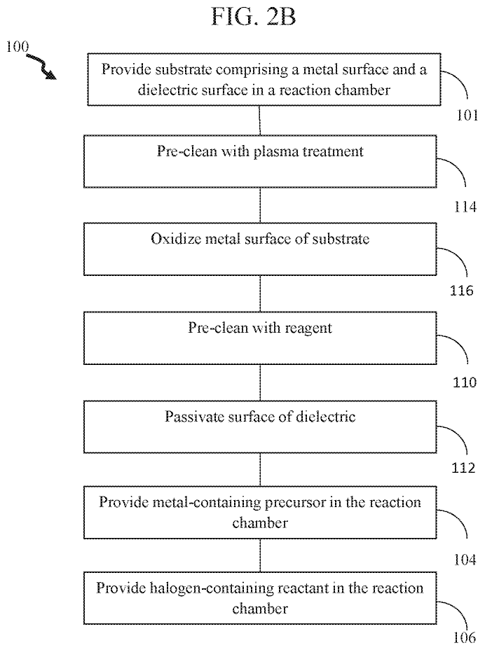

FIGS. 2A and 2B illustrate a block diagram of an exemplary embodiment of a method 100 of selectively depositing metal-containing material on a substrate comprising a metal surface and a dielectric surface. FIG. 2A illustrates an exemplary embodiment of a method 100 for fresh substrates, which may not be oxidized or have BTA on the surface, and therefore may not need to be pre-cleaned with plasma and subsequently intentionally oxidized. In the first phase 102, a substrate comprising a metal surface and a dielectric surface is provided into a reaction chamber. A substrate according to the current disclosure may comprise, for example, an oxide surface, such as silicon oxide surface (for example thermal silicon oxide or native silicon oxide), and a metal surface, such as copper, cobalt or tungsten. The metal-containing material according to the current disclosure may be deposited on said metal surface.

In phase 110, the substrate is pre-cleaned with a reagent. The pre-cleaning with a reagent cleans at least the metal surface of the substrate by removing any metal oxide present on the metal surface. After phase 110, the substrate is clean. Also, after phase 110, the dielectric surface of the substrate is passivated by applying an inhibitor reactant on the dielectric surface 112. This enhances the selectivity of the at least one selective deposition cycle. The selectivity is enhanced by passivating the dielectric surface, meaning that the deposited material does not grow on the passivated surface. After phase 112, at least one selective deposition cycle is executed by providing metal-containing precursor in the reaction chamber 104 and providing halogen-containing reactant in the reaction chamber 106. Optionally, the two phases 104 and 106, namely providing the precursor and the reactant in the reaction chamber, may be repeated (loop 108). Optionally, the reaction chamber is purged between providing metal-containing precursor and providing halogen-containing reactant (105, 107, as depicted in FIG. 1B).

FIG. 2B illustrates an exemplary embodiment of a method 100 for aged or fresh substrates, which may be oxidized or have BTA on the surface, and therefore need to be pre-cleaned with plasma and subsequently intentionally oxidized. In the first phase 101, a substrate comprising a metal surface and a dielectric surface is provided into a reaction chamber.

In the second phase 114, the metal surface of the substrate is pre-cleaned with plasma. The plasma may comprise direct plasma comprising hydrogen ions generated in the reaction chamber. The plasma pre-cleaning removes any metal oxide impurities that may exist on the metal surface. The plasma pre-cleaning may also remove benzotriazole (BTA) that may exist on the substrate. In the third phase 116, the metal surface of the substrate is intentionally oxidized, which leads to the formation of a metal oxide layer on the metal surface of the substrate. After the oxidation, phases 110, 112, 104, 106 are performed, and the optional phases 108, 105, and 107 may be performed.

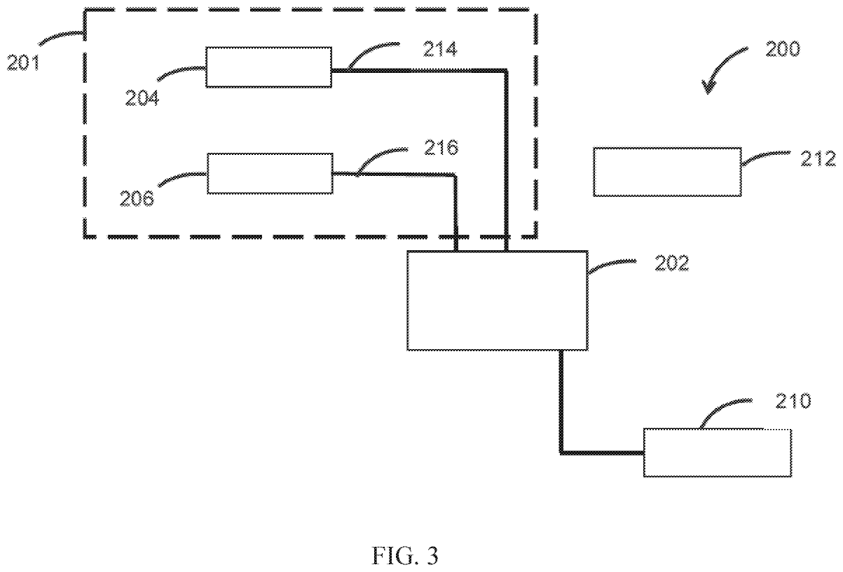

FIG. 3 illustrates a deposition assembly 200 according to the current disclosure in a schematic manner. Deposition assembly 200 can be used to perform a method as described herein and/or to form a structure or a device, or a portion thereof as described herein.

In the illustrated example, deposition assembly 200 includes one or more reaction chambers 202, a precursor injector system 201, a metal-containing precursor vessel 204, a reactant vessel 206, an exhaust source 210, and a controller 212. The deposition assembly 200 may comprise one or more additional gas sources (not shown), such as an inert gas source, a carrier gas source and/or a purge gas source.

Reaction chamber 202 can include any suitable reaction chamber, such as an ALD or CVD reaction chamber as described herein. Reaction chamber 202 may include a substrate support for supporting a substrate as described herein.

The metal-containing precursor vessel 204 can include a vessel and one or more metal-containing precursors as described herein-alone or mixed with one or more carrier (e.g., inert) gases. A reactant vessel 206 can include a vessel and a reactant comprising a halogen as described herein-alone or mixed with one or more carrier gases. Although illustrated with two source vessels 204, 206, deposition assembly 200 can include any suitable number of source vessels. Source vessels 204, 206 can be coupled to reaction chamber 202 via lines 214, 216, which can each include flow controllers, valves, heaters, and the like. In some embodiments, the metal-containing precursor in the metal-containing precursor vessel 204 and the reactant in the second precursor vessel 206 may be heated. In some embodiments, a vessel is heated so that a precursor or a reactant reaches a temperature between, for example, about 30 °C and about 140 °C, depending on the properties of the chemical in question.

Exhaust source 210 can include one or more vacuum pumps.

Controller 212 includes electronic circuitry and software to selectively operate valves, manifolds, heaters, pumps and other components included in the deposition assembly 200 to carry out a method as described herein. Such circuitry and components operate to introduce precursors, reactants and purge gases from the respective sources. Controller 212 can control timing of gas pulse sequences, temperature of the substrate and/or reaction chamber 202, pressure within the reaction chamber 202, and various other operations to provide proper operation of the deposition assembly 200. Controller 212 can include control software to electrically or pneumatically control valves to control flow of precursors, reactants and purge gases into and out of the reaction chamber 202. Controller 212 can include modules such as a software or hardware component, which performs certain tasks. A module may be configured to reside on the addressable storage medium of the control system and be configured to execute one or more processes.

Other configurations of deposition assembly 200 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 202. Further, as a schematic representation of a deposition assembly, many components have been omitted for simplicity of illustration, and such components may include, for example, various valves, manifolds, purifiers, heaters, containers, vents, and/or bypasses.

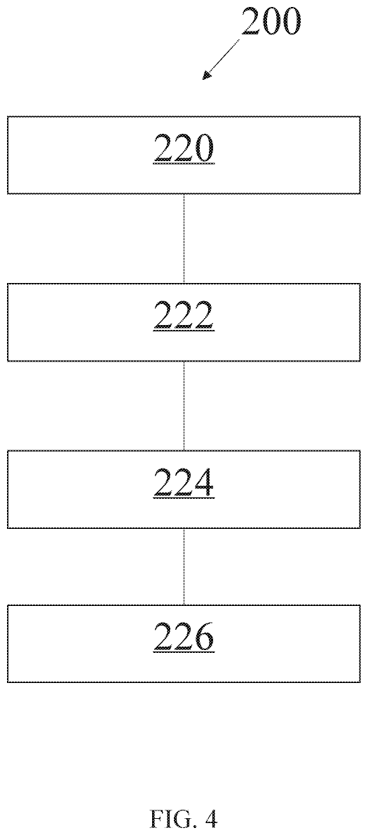

In some embodiments, as shown in FIG. 4, the deposition assembly comprises a plurality of modules to carry out aspects of the processes described herein. For example, the deposition assembly may comprise one or more of a pre-clean module 220 configured or arranged for carrying out any treatment as disclosed herein, e.g., plasma pre-cleaning, reagent pre-cleaning, and/or passivation, on the substrate prior to deposition of material on the substrate; a deposition module 222 configured or arranged for depositing metal-containing material on the pre-cleaned or treated substrate by a method as disclosed herein; a cooling station 224 configured and arranged to cool the substrate and oxidize the metal surface of the substrate according to a method as disclosed herein; and/or a capping station 226 configured and arranged to provide a capping layer on the deposited layer after at least one selective deposition cycle according to a method disclosed herein.

During operation of deposition assembly 200, substrates, such as semiconductor wafers (not illustrated), are transferred from, e.g., a substrate handling system to reaction chamber 202. Once substrate(s) are transferred to reaction chamber 202, one or more gases from gas sources, such as precursors, reactants, carrier gases, and/or purge gases, are introduced into reaction chamber 202 according to a method as described herein.

In some embodiments, the metal-containing precursor is supplied in pulses, the reactant is supplied in pulses and the reaction chamber is purged between consecutive pulses of a metal-containing precursor and a reactant.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing a material comprising metal on a substrate, the method comprising:
providing a substrate comprising a metal surface and a dielectric surface in a reaction chamber;
executing at least one selective deposition cycle, wherein the at least one selective deposition cycle comprises:
providing a metal-containing precursor in vapor phase into the reaction chamber,
wherein the metal-containing precursor comprises an η⁶-arene ligand and a metal selected from Cr, Mo, Nb, Ta, V, or W; and
providing a reactant in vapor phase into the reaction chamber, wherein the reactant comprises a halogen,
to form a layer comprising the material comprising metal on the metal surface of the substrate.

2. The method according to claim 1, further comprising pre-cleaning the substrate with a reagent before the at least one selective deposition cycle, in order to etch residual metal oxide from the metal surface.

3. The method according to claim 2, wherein the reagent is selected from the group consisting of glyoxal, malondialdehyde, succinaldehyde, phtalaldehyde, glutaraldehyde, isophtalaldehyde, adipaldehyde, 2,3-butandione, 2,3-pentandione, 2,3-hexandione, benzil, dimedone, 1,2-indandione, acetylacetone, trifluoroacetylacetone, hexafluoroacetylacetone, 1,3-cyclohexanedione, 2,2,6,6-tetramethyl-3,5-heptanedione, 2,5-hexandione, and methylglyoxal.

4. The method according to claim 1, further comprising pre-cleaning the substrate with plasma, wherein the plasma comprises remote plasma or direct plasma comprising hydrogen ions generated in the reaction chamber.

5. The method according to claim 2, further comprising oxidizing the metal surface of the substrate before the pre-cleaning with the reagent, to form a metal oxide layer on the metal surface.

6. The method according to claim 1, further comprising passivating the dielectric surface before the at least one selective deposition cycle.

7. The method according to claim 1, wherein the reactant comprises a compound according to Formula (I):
SiₓH_{(2x+2-y)}A_{y} (I)
wherein x is an integer from 1 to 10,
wherein y is an integer from 1 to 10, and
wherein A comprises a halogen.

8. The method according to claim 1, wherein the method is performed at 400 °C or less.

9. The method according to claim 1, wherein the reactant comprises an alkyl group.

10. The method according to claim 6, wherein the passivating of the dielectric surface comprises applying an inhibitor reactant comprising silicon on the dielectric surface, whereby selectivity of the at least one selective deposition to the metal surface is enhanced.

11. The method according to claim 7, wherein x is an integer from 1 to 3.

12. The method according to claim 7, wherein is an integer from 1 to 4.

13. The method according to claim 1, further comprising cooling the substrate and depositing a capping layer on the deposited layer after the at least one selective deposition cycle.

14. The method according to claim 1, wherein the reactant is selected from the group consisting of iodosilane, iododisilane, 1,2-diiododisilane, tetraiodosilane, chlorosilane, chlorodisilane, 1,2-dichlorodisilane, tetrachlorosilane, bromosilane, bromodisilane, 1,2-dibromodisilane, tetrabromosilane, ethyl iodosilane, diiododimethylsilane, iodotrimethylsilane, ethyl chlorosilane, dichlorodimethylsilane, chlorotrimethylsilane, ethyl bromosilane, dibromodimethylsilane, bromotrimethylsilane, 1,2-diiodoethane, iodobutane, 1,2-dichloroethane, chlorobutane, 1,2-dibromoethane, and bromobutane.

15. The method according to claim 10, wherein the inhibitor reactant has a formula SiR₃NR′₂, wherein each R is independently selected from C1 to C5 alkyls and alkoxides, and each R′ is independently selected from C1 to C7 alkyls.

16. The method according to claim 1, wherein the at least one selective deposition cycle is performed at a temperature of from 150 °C to 400 °C.

17. The method according to claim 1, wherein the metal-containing precursor and the reactant are provided into the reaction chamber in pulses and the reaction chamber is purged between consecutive pulses.

18. The method according to claim 1, wherein the metal-containing precursor comprises bis(ethylbenzene)molybdenum, and wherein the layer comprises metallic molybdenum or molybdenum carbide.

19. A semiconductor processing apparatus comprising:
a reaction chamber comprising a substrate support for supporting a substrate comprising a metal surface and a dielectric surface;
a precursor injector system constructed and arranged to provide a metal-containing precursor and a reactant into the reaction chamber in a vapor phase;
a metal-containing precursor source constructed and arranged to contain and evaporate the metal-containing precursor, wherein the metal-containing precursor comprises an η⁶-arene ligand and a metal selected from Cr, Mo, Nb, Ta, V, or W;
a reactant source constructed and arranged to contain and evaporate the reactant, wherein the reactant comprises a halogen; and
a controller configured to provide the metal-containing precursor and the reactant via the precursor injector system to the reaction chamber to deposit a metal-containing layer on the substrate according to the method of claim 1.

20. The semiconductor processing apparatus according to claim 19, the semiconductor processing apparatus further comprising a pre-clean module and optionally a cooling station.
